(19) United States
(12) Patent Application Publication
(10) Pub. No.: US 2026/0005700 A1
(43) Pub. Date: Jan. 1, 2026

(54) ANALOG-TO-DIGITAL CONVERTER WITH GRAY COUNTER

(71) Applicant: ams Sensors Belgium BV, Antwerpen (BE)

(72) Inventor: Koen RUYTHOOREN, Hever (BE)

(21) Appl. No.: 19/109,489

(22) PCT Filed: Aug. 31, 2023
(86) PCT No.: PCT/EP2023/073946

§ 371 Date: Mar. 6, 2025

(30) Foreign Application Priority Data
Sep. 13, 2022 (DE) 10 2022 123 292.1

(51) Int. Cl. H03M 1/12; H03K 3/037; H03K 21/08; H04N 25/771; H04N 25/772; H04N 25/779

(52) U.S. Cl. CPC H03M 1/12; H03K 21/08; H04N 25/771; H04N 25/772; H04N 25/779; H03K 3/037

(57) ABSTRACT

An analog-to-digital converter (ADC) includes a plurality of ADC circuits. Each ADC circuit is associated to a pixel group of a pixel array and includes a storage circuit including a plurality of storage cells. The ADC also includes a shared counter circuit having a counter control connection to apply a clock signal and a plurality of counter output connections. The shared counter circuit is configured to generate a respective counter bit in response to a counter state of the counter circuit. A respective one of the storage cells is connected to a respective one of the counter output connections for storing the respective counter bit. The shared counter circuit comprises a Gray ripple counter. The ADC further includes a delay circuit. The delay circuit is arranged on at least one of the counter output connections between the counter circuit and a corresponding storage cell.

An analog-to-digital converter (ADC) is a system that converts an analog signal, such as a sound picked up by a microphone or light entering a digital camera, into a digital signal. More specifically, the ADC converts an analog input voltage or current to a digital number representing the magnitude of the voltage or current, which may then be read and processed by a microcontroller. In this context, several ADCs with different ADC architectures are known and used as integrated circuits (ICs) in different systems.

For example, an image sensor commonly uses an ADC with a counter-ramp ADC architecture to read out the voltages of an array of pixels of the image sensor. In this type of ADC, a comparator circuit compares a group voltage level (e.g., a column voltage level) of a pixel of a pixel group (e.g., a pixel of a pixel column) with a periodic ramp voltage. The time between the ramp start and a toggling of the output of the comparator circuit (i.e., when the periodic ramp voltage crosses the column voltage level, which is also known as the comparator circuit's toggle time) is tracked using an n-bit counter circuit. The output signal including corresponding counter bits of the counter circuit serves as a digital representation of the column voltage. This value is usually stored after the conversion.

In such a counter-ramp ADC architecture, a binary ripple counter is generally used, which is shared over multiple columns to determine the comparator circuit's toggle time. For N bits this implies 2^{N+1} bit toggles that need to be converted. When the comparator circuit toggles the counter bits are latched or stored per column. However, a corresponding control signal for latching the counter bits needs to be synchronized to an ADC clock to ensure that all counter bits are sampled on the same counter code. That is, a synchronization is required per column, where the ADC clock needs to be distributed to all columns of the pixel array. A wrong sampling of a bit could amount to an error of up to 2^{N-1}. This need for synchronization results in a higher power consumption. Furthermore, since up to N-1 bits may toggle at the same time there may be no clean change from one count to the next. That is, there may be intermediate values present during switching.

To alleviate the need of synchronization a Gray counter may be used instead. In a Gray counter the difference between two consecutive counter values is only 1 bit flip, so no synchronization to an ADC clock is needed. More specifically, no synchronization of a control signal for latching the counter bits to the ADC clock is required. For N bits there are only 2^{N} bit toggles, where one bit may toggle at the same time. This results in a constant power over a full count range, where a clean change from one count to the next is provided. Thus, no intermediate states are present. And a wrong sampling of a bit amounts only to a small error.

A simple way to implement such a Gray counter is to use a binary ripple counter and to derive the gray codes (or gray bits) via additional flip-flops. However, due to the bit delays in the binary ripple counter not all counts (e.g., codes) have the same length. For example, if a latch time (e.g., a time when latching or writing bits to memory) is asynchronous to a counter clock, differential nonlinearity (DNL) is introduced between converted bits or codes. In this regard, DNL is a commonly used measure of performance in a digital-to-analog converter (DAC) or an ADC and describes the deviation between two analog values corresponding to adjacent input digital values. For example, if the total delay between a most significant bit (MSB) and a least significant bit (LSB) is longer than the counter clock period, some codes may not even exist when all bits are latched at the same time. In addition, ripple delays limit the maximum speed of the counter. Furthermore, clocking at high frequencies implies a smaller sample window and thus larger errors, i.e., larger DNL values.

In view of the above, it is an object of the present invention to provide an improved ADC with a Gray counter.

### SUMMARY

According to embodiments, an analog-to-digital converter (ADC) comprises a plurality of ADC circuits, each ADC circuit being associated to a pixel group of an pixel array and comprising a storage circuit comprising a plurality of storage cells, a shared counter circuit having a counter control connection to apply a clock signal and a plurality of counter output connections, the shared counter circuit being configured to generate a respective counter bit in response to a counter state of the counter circuit, wherein a respective one of the storage cells is connected to a respective one of the counter output connections for storing the respective counter bit, wherein the shared counter circuit comprises a Gray ripple counter, and a delay circuit, the delay circuit being arranged on at least one of the counter output connections between the counter circuit and a corresponding storage cell and being configured to add to at least one counter bit a bit-specific delay.

According to embodiments, an analog-to-digital converter (ADC) comprises a plurality of ADC circuits, each ADC circuit being associated to a pixel group of an pixel array and comprising a storage circuit comprising a plurality of storage cells, a shared counter circuit having a counter control connection to apply a clock signal and a plurality of counter output connections, the shared counter circuit being configured to generate a respective counter bit in response to a counter state of the counter circuit, wherein a respective one of the storage cells is connected to a respective one of the counter output connections for storing the respective counter bit, wherein the shared counter circuit comprises a Gray ripple counter, and a delay circuit connected to one or more storage cells of the plurality of storage cells and configured to delay a write control signal for storing a counter bit into a storage cell of the one or more storage cells, wherein the delay for the write control signal increases from lower counter bits to higher counter bits.

The bit-specific delay added to a counter bit or the delay added to a write control signal for storing respective counter-bits accounts for the ripple delay introduced by the Gray ripple counter.

For example, the bit-specific delay added to a counter bit may differ from counter-bit to counter bit. And the delayed write control signal for storing a counter bit increase from lower counter bits to higher counter bits. That is, the delay may be adapted for each counter bit or the write control signal such that it matches a ripple delay introduced by the Gray ripple counter. Adding such a delay may result in codes that have the same length. This reduces the possibility of missing code, and thus, minimizes the DNL.

The Gray ripple counter may comprise a binary ripple counter that generates the binary output bits and an additional set of flip-flops. The binary output bits may be used as input into the set of flip-flops to generate the counter bits. The counter bits may correspond to the Gray counter bits.

The bit-specific delay added to a counter bit may match a delay of the preceding counter bit generated by the binary ripple counter. Specifically, starting from the lowest counter bit, i.e. the least significant bit (LSB) to the highest counter bit, i.e., the most significant bit (MSB), the delay added to successive counter bits equals the delay of the respective preceding bit.

According to embodiments, a number of delay units of the delay circuit may increase from the storage cells assigned to lower counter bits to the storage cells assigned to higher counter bits. This accumulated delay may allow to account for the ripple delay.

The ADC may also comprise a comparator circuit configured to generate a comparison signal in response to a comparison of an input signal and a reference signal, wherein the comparison signal is input into each one of the ADC circuits. The control write signal may be based on the comparison signal. For example, the counter bits may be generated until the comparison signal indicates that the comparator circuit toggles.

In addition, the shared counter circuit may comprise a further Gray ripple counter.

In greater detail, the Gray ripple counter may be configured to change its counter state, when a first edge of a clock cycle of a clock signal is applied to the Gray ripple counter. The further Gray ripple counter may be configured to change its counter state, when a second edge of the clock cycle of the clock signal being opposite to the first edge of the clock cycle of the clock signal is applied to the further Gray ripple counter.

Using the Gray ripple counter and the additional Gray ripple counter and clocking these counters on the opposite clock edge may result in a speed factor of two, since there may be both a rising edge and a falling edge counter.

Furthermore, the Gray ripple counter may be connected to a first portion of the storage cells of each of the storage circuits. And the further Gray ripple counter may be connected to a second portion of each of the storage cells of the storage circuits.

The storage cells may be static random-access memory (SRM) cells.

The pixel group may correspond to a column of the pixel array.

Furthermore, the ADC may be configured as a column-parallel ADC.

The above object may also be solved by an image sensor, comprising: a pixel array including at least two pixel groups, each pixel group comprising a plurality of pixels connected to a respectively associated group bus of that pixel group, and an analog-to-digital converter as described above.

The above object may also be solved by a Gray ripple counter, comprising: a binary ripple counter configured to output binary counter bits, a set of flip-flops configured to receive the binary counter bits as input and to generate Gray counter bits, and a delay circuit arranged at an output of the binary ripple counter and configured to add to the binary counter bits a bit-specific delay.

### BRIEF DESCRIPTION OF THE DRAWINGS

The accompanying drawings are included to provide a further understanding of embodiments of the invention and are incorporated in and constitute a part of this specification. The drawings illustrate the embodiments of the present invention and together with the description serve to explain the principles. Other embodiments of the invention and many of the intended advantages will be readily appreciated, as they become better understood by reference to the following detailed description. The elements of the drawings are not necessarily to scale relative to each other. Like reference numbers designate corresponding similar parts.

FIG. 1A is a schematic diagram illustrating an image sensor according to embodiments.

FIG. 1B is a schematic diagram illustrating an ADC according to embodiments.

FIG. 2A is a schematic diagram illustrating an ADC according to embodiments.

FIG. 2B is a schematic diagram illustrating an ADC according to embodiments.

FIG. 3A is a schematic diagram illustrating a Gray ripple counter according to embodiments.

FIG. 3B is a schematic diagram illustrating a Gray ripple counter according to embodiments.

FIG. 4A is a schematic diagram of an output of a Gray ripple counter.

FIG. 4B is a schematic diagram of an output of a Gray ripple counter according to embodiments.

FIG. 4C is a schematic diagram of an output of a Gray ripple counter according to embodiments.

### DETAILED DESCRIPTION

In the following detailed description reference is made to the accompanying drawings, which form a part hereof and in which are illustrated by way of illustration specific embodiments in which the invention may be practiced. In this regard, directional terminology such as “top”, “bottom”, “front”, “back”, “over”, “on”, “above”, “leading”, “trailing” etc. is used with reference to the orientation of the Figures being described. Since components of embodiments of the invention can be positioned in a number of different orientations, the directional terminology is used for purposes of illustration and is in no way limiting. It is to be understood that other embodiments may be utilized and structural or logical changes may be made without departing from the scope defined by the claims.

The description of the embodiments is not limiting. In particular, elements of the embodiments described hereinafter may be combined with elements of different embodiments.

As employed in this specification, the terms “coupled” and/or “electrically coupled” are not meant to mean that the elements must be directly coupled together-intervening elements may be provided between the “coupled” or “electrically coupled” elements. The term “electrically connected” intends to describe a low-ohmic electric connection between the elements electrically connected together.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

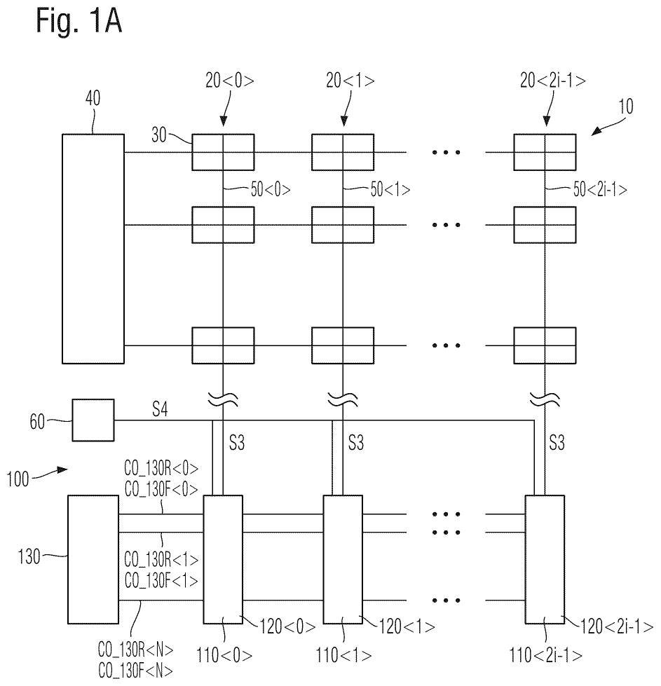

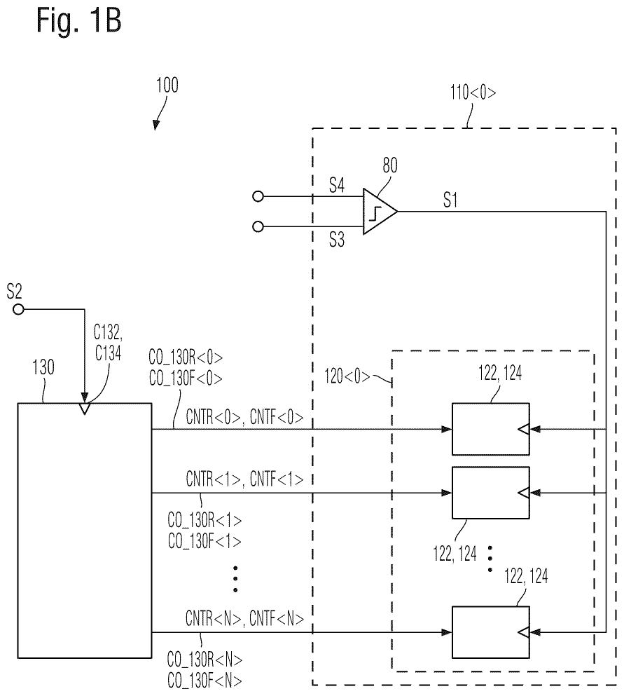

FIG. 1A is a schematic diagram illustrating an image sensor 1 according to embodiments. The image sensor 1 comprises a pixel array 10 including a plurality of pixel groups 20<0>, 20<1>, . . . , 20<i-1>, . . . , 20<i>, . . . , 20<2i-1>, for example pixel columns. Each of the pixel groups/columns 20<0>, 20<1>, . . . , 20<i-1>, . . . , 20<i>, . . . , 20<2i-1> comprises a plurality of pixels 30 connected to a respectively associated group/column bus 50<0>, 50<1>, . . . , 50<i-1>, . . . , 50<i>, . . . , 50<2i-1> of the respective pixel group/column 20<0>, 20<1>, . . . , 20<i-1>, . . . , 20<i>, . . . , 20<2i-1>. However, different arrangements of pixel groups may be possible.

The image sensor 1 may further comprise a row selection circuit 40 to select one of the pixel rows for reading out the content of the pixels 30 arranged in the selected row.

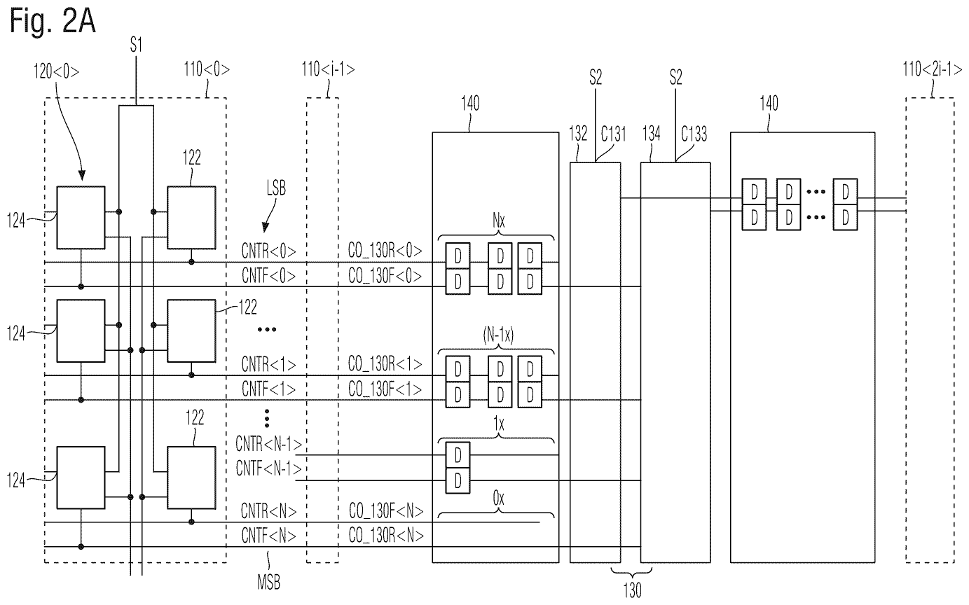

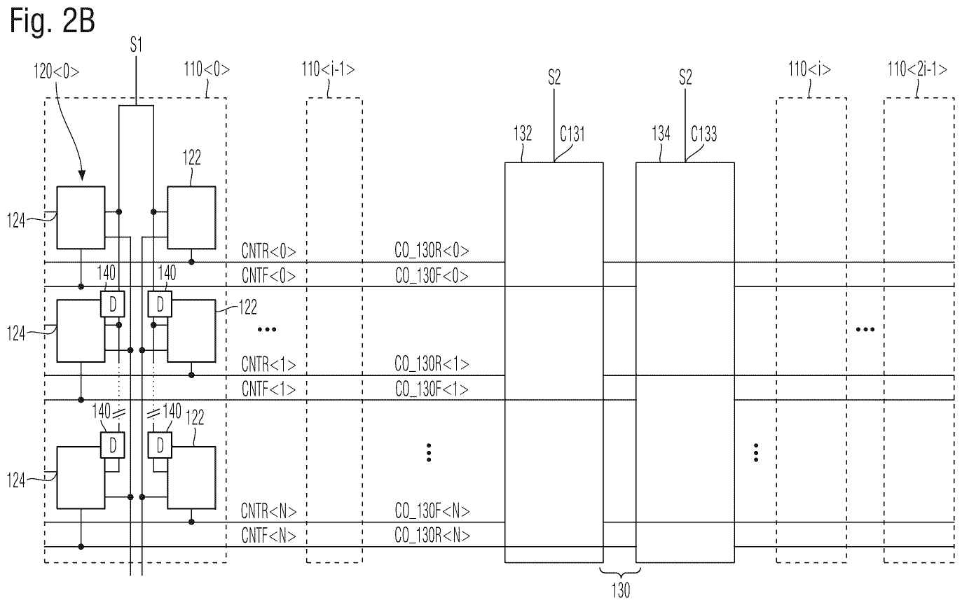

In addition, the image sensor 1 comprises an analog-to-digital converter (ADC) 100 being configured to read out voltage levels of the pixels 30 of the pixel array 10 which are selected for reading-out. The ADC 100 comprises a plurality of group/column ADC circuits 110<0>, 110<1>, . . . , 110<i-1>, . . . , 110<i>, . . . , 110<2i-1>. Each of the group/column ADC circuits 110<0>, 110<1>, . . . , 110<i-1>, . . . , 110<i>, . . . , 110<2i-1> is associated to one of the pixel groups/columns 20<0>, 20<1>, . . . , 20<i-1> . . . , 20<i>, . . . , 20<2i-1>. A counter circuit 130 of the ADC 100 is shared between the <2i-1> pixel groups/columns or the <2i-1> group/column ADC circuits 110<0>, 110<1>, . . . , 110<i-1>, . . . , 110<i>, . . . , 110<2i-1>. In FIG. 1A, the counter circuit 130 is arranged on one side of the ADC circuits 110<0>, 110<1>, . . . , 110<i-1>, . . . , 110<i>, . . . , 110<2i-1>. However, it may be arranged at arbitrary locations depending on requirements placed on the ADC architecture. For example, it may be arranged in the middle of the ADC circuits 110<0>, 110<1>, . . . , 110<i-1>, . . . , 110<i>, . . . , 110<2i-1>, e.g., between ADC circuit <i-1> and ADC circuit<i>. Furthermore, other components may be located between the group/column bus lines 50<0>, 50<1>, . . . , 50<i-1>, . . . , 50<i>, . . . , 50<2i-1> and the group/column ADC circuits 110<0>, 110<1>, . . . , 110<i-1>, . . . , 110<i>, . . . , 110<2i-1> such as e.g., a delay circuit 140 (not shown in FIGS. 1A and 1B). Examples of configurations of such ADC 100 architectures are going to be explained in detail in relation to FIGS. 2A and 2B.

The ADC 100 as described above may be configured as a group-parallel ADC, for example a column-parallel ADC.

FIG. 1B shows the ADC circuit 110<0> of the ADC 100 according to embodiments to read out the voltage levels of the selected pixels 30 of the pixel array 10 of FIG. 1A. The configuration of the ADC circuit 110<0> applies to each ADC circuit of the plurality of ADC circuits 110<1>, . . . , 110<i-1>, . . . , 110<i>, . . . ,110<2i-1> comprised in the ADC 100. That is, the ADC circuit 110<0> is being representative for the plurality of ADC circuits 110<0>, 110<1>, . . . , 110<i-1>, . . . , 110<i>, . . . , 110<2i-1>. The ADC circuit 110<0> may comprise an input terminal to apply an input signal S3 provided from the selected pixel column to read out the voltage level of the pixels 30 of the selected row. The ADC circuit 110<0> may further comprise a reference terminal to apply a reference signal S4. The reference signal S4 may be generated by a ramp voltage generator 60 shown in FIG. 1A.

As further illustrated in FIG. 1B, the counter circuit 130 has a counter control connection C132, C134 to apply a clock signal S2 and a plurality of counter output connections CO_130R<0>, CO_130R<1>, . . . , CO_130R<N>, CO_130F<0>, CO_130F<1>, . . . , CO_130F<N> to generate a respective counter bit CNTR<0>, CNTR<1>, . . . , CNTR<N>, CNTF<0>, CNTF<1>, . . . , CNTF <N> in response to a counter state of the counter circuit 130. Referring to the above example, the counter bits CNTR<0>, CNTR<1>, . . . , CNTR<N>, CNTF<0>, CNTF<1>, . . . , CNTF <N> may represent the digital representation of the column voltage. The ADC circuit 110<0> further comprises a storage circuit 120<0> comprising a plurality of storage cells 122, 124. A respective one of the storage cells 122, 124 is connected to a respective one of the counter output connections CO_130R<0>, CO_130R<1>, . . . , CO_130R<N>, CO_130F<0>, CO_130F<1>, . . . , CO_130F<N> for storing the respective counter bit CNTR<0>, CNTR<1>, . . . , CNTR<N>, CNTF<0>, CNTF<1>, . . . , CNTF <N>.

The ADC circuit 110<0> of the ADC 100 may also comprise a comparator circuit 80 for generating a level of a comparison signal S1 in response to a comparison of the input signal S3 and the reference signal S4. According to examples, the comparator circuit 80 may also be arranged outside the ADC circuit 110<0>. The comparison signal S1 may indicate when the comparator circuit 80 toggles, i.e., when the input signal S3 such as the voltage level of the pixel 30 of the pixel column crosses the reference signal S4 such as the periodic ramp voltage. For example, when the comparator circuit 80 toggles a latching-or storing/writing-process in the storage cells 122, 124 of the ADC circuit 110<0> may be stopped.

FIGS. 2A and 2B are schematic diagrams illustrating an analog-to-digital converter (ADC) 100 according to embodiments in more detail. These ADC architectures may be employed in the image sensor 1 as shown in FIG. 1A. As described with reference to FIGS. 1A and 1B, the ADC 100 comprises the plurality of ADC circuits 110<0>, . . . , 110<i-1>, . . . , 110<2i-1> and the shared counter circuit 130.

Similar to FIGS. 1A and 1B, the exemplary ADC circuit 110<0> shown in FIGS. 2A and 2B is representative for the remaining ADC circuits 110<i-1>, . . . , 110<i>, . . . , 110<2i-1> indicated by dashed rectangles. As described above, the ADC circuits 110<i-1>, . . . , 110<i>, . . . , 110<i-1>, . . . , 110<2i-1> may be configured as column ADC circuits associated to respective pixel columns 20<i-1>, . . . , 20<i>, . . . , 20<2i-1> of the pixel array 10 (not shown in FIGS. 2A and 2B). However, other configurations are possible. The ADC circuits 110<0>, . . . , 110<i-1>, . . . , 110<i>, . . . , 110<2i-1> may receive the comparison signal S1 generated by the comparator circuit 80 (not shown in FIGS. 2A and 2B).

The shared counter circuit 130 generates the counter bits CNTR<0>, CNTR<1>, . . . , CNTR<N>, CNTF<0>, CNTF<1>, . . . , CNTF<N> in response to a counter state of the counter circuit 130. Moreover, a respective one of the storage cells 122, 124 is connected to a respective one of the counter output connections CO_130R<0>, . . . , CO_130R<N>, CO_130F<0>, . . . , CO_130F<N> for storing the respective counter bit CNTR<0>, . . . , CNTR<N>, CNTF<0>, . . . , CNTF<N>.

In greater detail, the shared counter circuit 130 comprises a Gray ripple counter 132, 134. FIGS. 2A and 2B illustrate two Gray ripple counters 132, 134, which are shared between the ADC circuits 110<0>, . . . , 110<i-1>, . . . , 110<i>, . . . , 110<2i-1>. However, a configuration of the counter circuit 130 comprising only one single Gray ripple counter 132, 134 is also possible.

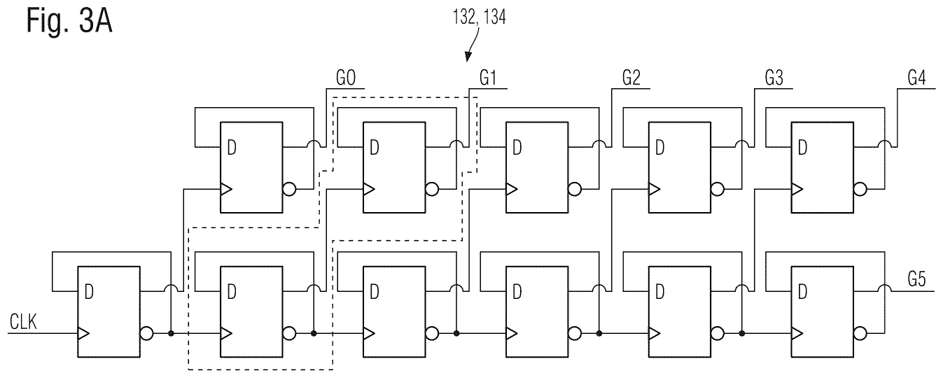

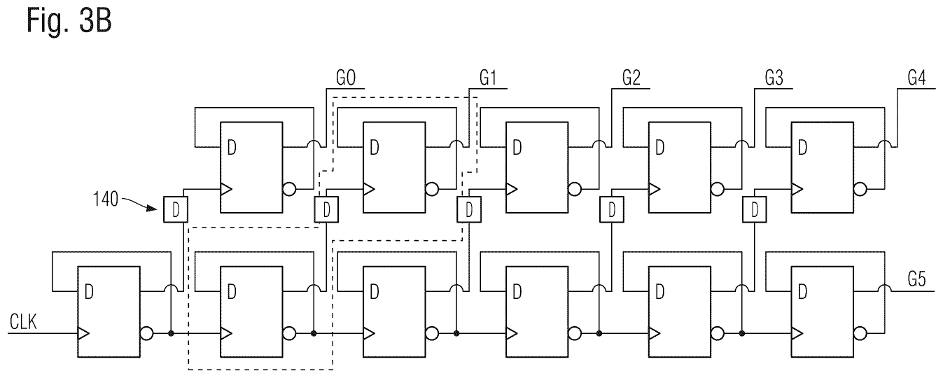

Generally, asynchronous counters such as ripple counters may be formed by several flip-flops that are connected in cascade. FIG. 3 is a schematic diagram illustrating a Gray ripple counter 132, 134 according to embodiments. The Gray ripple counter 132, 134 may be implemented by using a binary ripple counter that generates binary output bits B0, B1, B2, B3, . . . , BN. Subsequently, corresponding Gray output bits respectively Gray counter bits G0, G1, G2, G3, . . . , GN (i.e., the counter bits CNTR<0>, CNTR<1>, . . . , CNTR<N>, CNTF<0>, CNTF<1>, . . . , CNTF<N>) are generated from the binary bits B0, B1, B2, B3, . . . , BN.

One drawback of such a ripple counter 132, 134 is caused by its basic principle of operation. Each flip-flop 136 is triggered by the transition of the output of the preceding flip-flop 136, as indicated in FIG. 3. The effect of a clock signal S2 e.g., an input clock pulse CLK, is first “felt” by the first flip-flop 136. This effect cannot get to the next flip-flop 136 immediately because of the propagation delay time t_{pd} through the first flip-flop 136. Then there is the propagation delay through the next flip-flop 136 before the subsequent flip-flop 136 can be triggered. Thus, the effect of the input clock pulse CLK “ripples” through the Gray ripple counter 132, 134, taking some time, due to propagation delays, to reach the last flip-flop 136.

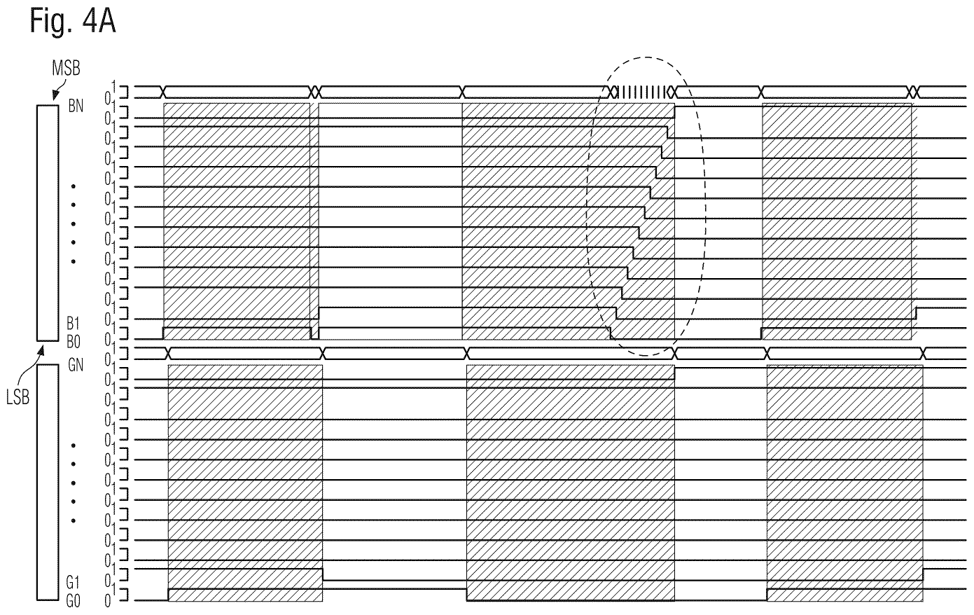

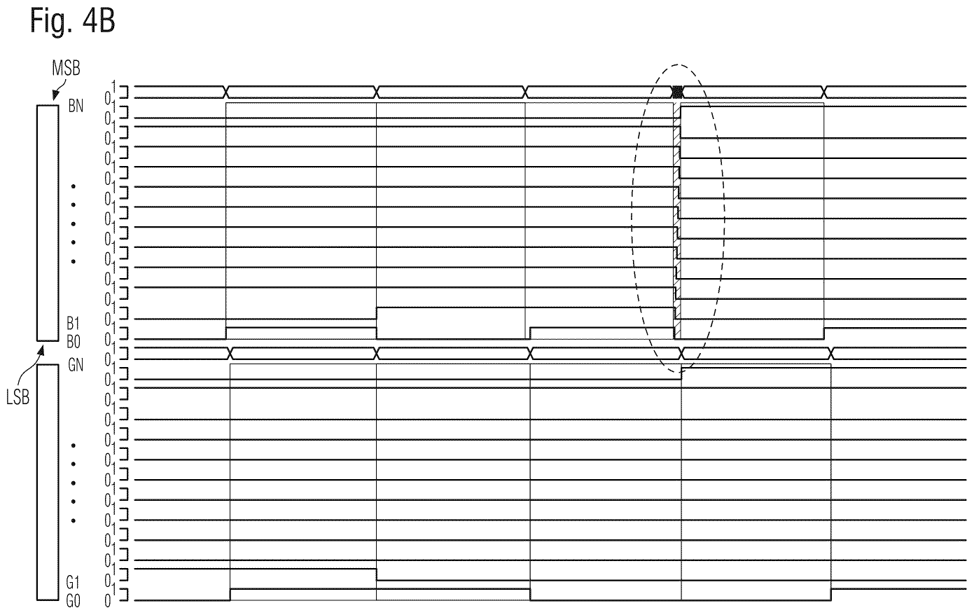

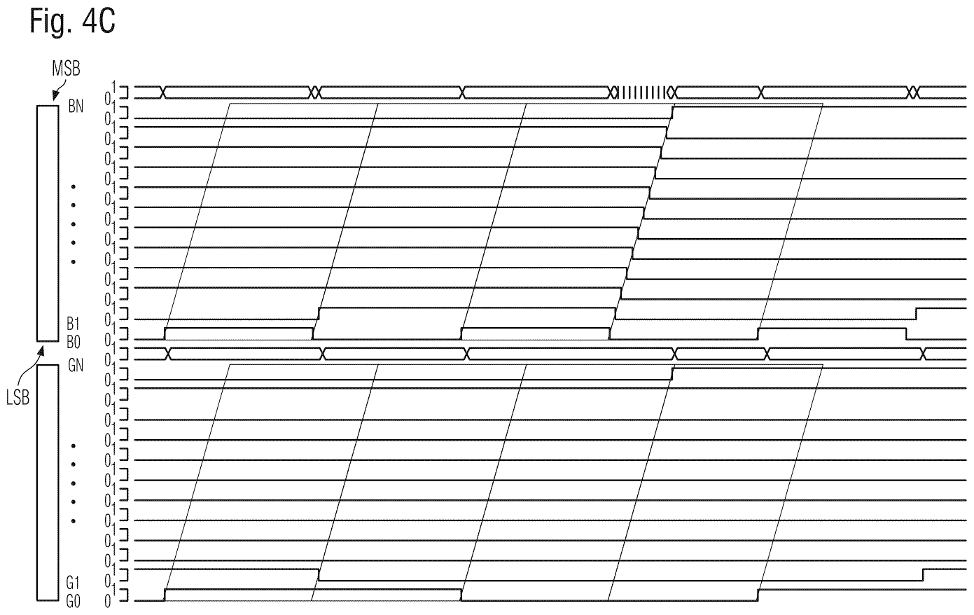

This means that the next flip-flop 136 will not respond until a time t_{pd} after the first flip-flop 136 receives an active clock transition, the subsequent flip-flop 136 will not respond until a time equal to 2*t_{pd} after that clock transition, and so on. In other words, according to the implementation shown in FIG. 3, the propagation delays of the flip-flops 136 may accumulate so that the Nth flip-flop 136 cannot change states until a time equal to N*t_{pd} after the clock transition occurs. This is illustrated in FIG. 4A, which schematically shows the ripple delay of the Gray ripple counter 132, 134. According to different implementations of the Gray ripple counter, different propagation delays are possible.

The upper portion in FIG. 4A shows the binary output or binary bits B0, B1, B2, B3, . . . , BN of the binary counter. The dashed circle shows a transition from a binary code, e.g. a binary code representing 2047 (wherein the most significant bit is at “0” and all other bits are at “1”), to the binary code representing 2048 (wherein the most significant bit is at “1” and all other bits are at “0”). In other words, during these transitions all bits are switched. As indicated by a dashed circle, the ripple delay propagates from the lowest bit, i.e., the least significant bit (LSB) derived by the first flip-flop 136 to the highest bit, i.e., the most significant bit (MSB) derived by the last flip-flop 136. For example, the LOW-to-HIGH transition of B0 occurs one delay time after the positive transition of the input clock pulse CLK. The LOW-to-HIGH transition of B1 occurs one delay time t_{pd} after the positive-going transition of B1, and so on. When all bits are sampled at the same point in time during this transition time, an error due to the delay will occur.

Due to this delay not all gray codes or counts have the same length. This is further apparent in the lower portion of FIG. 4A. The lower portion shows the Gray output or Gray bits G0, G1, G2, G3, . . . , GN of the Gray counter. For example, if the total delay between the MSB and LSB is longer than the clock period, some codes may not even exist when all counter bits CNTR<0>, CNTR<1>, . . . , CNTR<N>, CNTF<0>, CNTF<1>, . . . , CNTF <N> are stored/written or latched at the same time.

In view of the above, the ADC configurations 100 of the present invention as shown in FIGS. 2A and 2B each comprises a delay circuit 140 that alleviates the effect of the ripple delay, as explained in the following.

According to embodiments shown in FIG. 2A, the ADC 100 comprises a delay circuit 140, the delay circuit being arranged on at least one of the counter output connections CO_130R<0>, . . . , CO_130R<N>, CO_130F<0>, . . . , CO_130F<N> between the counter circuit 130 and a corresponding storage cell 122, 124 and being configured to add to at least one counter bit CNTR<0>, . . . , CNTR<N>, CNTF<0>, . . . , CNTF<N> a bit-specific delay b_D. In FIG. 2A two counter circuits 140 are shown for the two Gray ripple counters 132, 134. However, a configuration with only one delay circuit 140 and Gray ripple counter 132, 134 may also be realized.

That configuration enables to add to a counter bit CNTR<0>, . . . , CNTR<N>, CNTF<0>, . . . , CNTF<N> a corresponding delay, where the delays between two consecutive counter bits CNTR<0>, . . . , CNTR<N>, CNTF<0>, . . . , CNTF<N> differ. In other words, the term bit-specific delay b_D is intended to mean that the delays b_D differ from counter bit to counter bit. For example, as indicated by small rectangles in the delay circuit 140 in FIG. 2A, the bit-specific delay b_D decreases from LSB to MSB. That is, the LSB has the highest amount of added delay, while the MSB has no delay added.

In greater detail, the bit-specific delay b_D may match a delay of the previous counter bit generated by the binary ripple counter 132, 143. Thus, every counter bit CNTR<0>, . . . , CNTR<N>, CNTF<0>, . . . , CNTF<N> may be delayed such that it has a similar delay as the MSB. This is shown in FIG. 4B, which is a schematic diagram of an output of the ADC 100 with the Gray ripple counter 132, 132 according to embodiments. As can be seen in the region indicated by a dashed circle in the upper portion of FIG. 4B, all binary bits B0, . . . , BN have the same delay. This results in Gray codes or counts having the same length. The resulting Gray counter bits G0, . . . , GN correspond to the counter bits CNTR<0>, . . . , CNTR<N>, CNTF<0>, . . . , CNTF<N> as shown in FIG. 1A.

According to embodiments shown in FIG. 2B, the ADC comprises a delay circuit 140 connected to one or more storage cells 122, 124 of the plurality of storage cells 122, 124. The delay circuit 140 delays a write control signal for storing a counter bit CNTR<0>, . . . , CNTR<N>, CNTF<0>, . . . , CNTF<N> into a storage cell 122, 124 of the one or more storage cells 122, 124. The delay for the write control signal increases from lower counter bits CNTR<0>, . . . , CNTR<N>, CNTF<0>, . . . , CNTF<N> to higher counter bits CNTR<0>, . . . , CNTR<N>, CNTF<0>, . . . , CNTF<N>.

In this configuration, each consecutive counter bit CNTR<0>, . . . , CNTR<N>, CNTF<0>, . . . , CNTF<N> as shown in FIG. 2B together with the counter output connections CO_130R<0>, . . . , CO_130R<N>, CO_130F<0>, . . . , CO_130F<N>, is written/stored or latched slightly later into a storage cell 122, 124 as the previous counter bit CNTR<0>, . . . , CNTR<N>, CNTF<0>, . . . , CNTF<N>. The delay for the write control signal thus increases in a manner that follows the ripple delay introduced by the Gray ripple counter 132, 134. That is, the counter bits CNTR<0>, . . . , CNTR<N>, CNTF<0>, . . . , CNTF<N> may be sampled at different moments in time. In this regard, FIG. 4C shows an output of the ADC 100 with the Gray ripple counter 132, 134 according to embodiments. Also in this case, the resulting Gray codes or counts have the same length. There is no missing code.

In this context, a number of delay units of the delay circuit 140 may increase from the storage cells 122, 124 assigned to lower counter bits CNTR<0>, . . . , CNTR<N>, CNTF<0>, . . . , CNTF<N> to the storage cells 122, 124 assigned to higher counter bits CNTR<0>, . . . , CNTR<N>, CNTF<0>, . . . , CNTF<N>. According to examples, the delay units may be configured to reproduce the delay of the Gray ripple counter, e.g., the flip-flops 136. That is they may be configured as replica or partial replica of the flip-flops 136. The delay may then track the ripple delay over processing, temperature and supply corners.

In view of the above, both ADC configurations of the present invention account for the ripple delay introduced by the Gray ripple counter 132, 134. The ADC configurations shown in FIGS. 2A and 2B comprise two Gray ripple counter 132, 134, which are described in further detail farther below. However, the ADC configuration may be realized with only one Gray ripple counter 132, 134.

As discussed above, the Gray ripple counter 132, 134 may comprise a binary ripple counter that generates the binary output bits B0, . . . , B and an additional set of flip-flops 136. This configuration is shown in FIG. 3, where the binary outputs bits B0, B1, B2, B3, . . . , B are used as input into the set of flip-flops 136 to generate the counter bits bit CNTR<0>, . . . , CNTR<N>, CNTF<0>, . . . , CNTF<N>, which may be the Gray counter bits G0, . . . , GN.

Due to the above configurations, it is possible to efficiently use the Gray ripple counter 132, 134 in the ADC 100, which reduces power consumption, since no synchronization is needed. The added delay may make the asynchronous counter appear synchronous. Furthermore, the described configurations allow to increase the ADC 100 counter frequency. Further, a possible error is only of the order of one DN or LSB.

The ADC configurations shown in FIGS. 2A and 2B comprise two Gray ripple counter 132, 134, which are described in further detail farther below. However, the ADC configuration may be realized with only one Gray ripple counter 132, 134.

Furthermore, FIG. 3B is a schematic diagram illustrating a Gray ripple counter 138 according to embodiments. This Gray ripple counter 138 differs from the one illustrated in FIG. 3A in that it comprises the delay circuit 140 arranged between the flip-flops 136. In other words, a bit-specific delay b_D is added to the Binary bits B0, . . . , BN that are input into the additional set of flip-flops 136 to generate the Gray counter bits G0, . . . , GN. This configuration may be used for example in the ADC circuit 100 as shown in FIG. 1A to account for the ripple delay as explained above.

As explained in relation to FIG. 1B, the ADC 100 may also comprise a comparator circuit 80 (not shown in FIGS. 2A and 2B) to generate the comparison signal S1 in response to a comparison of an input signal (e.g., a voltage level of a pixel) and a reference signal (e.g., a ramp reference voltage). The comparator circuit 80 may be realized in each one of the ADC circuits 110<0>, . . . , 110 <2i-1> or may be realized as a separate circuit. The comparison signal S1 may then be input into each one of the ADC circuits 110. Moreover, the control write signal may be based on the comparison signal S1.

As is further illustrated in FIGS. 2A and 2B, the shared counter circuit 130 may comprise a further Gray ripple counter 134.

The Gray ripple counter 132 may change its counter state, for example, when a first edge (e.g., a rising edge) of a clock cycle of a clock signal S2 is applied to the Gray ripple counter 132. And the further Gray ripple counter 134 may change its counter state, when a second edge (e.g., a falling edge) of the clock cycle of the clock signal S2 is applied to the further Gray ripple counter 134. For example, the second edge may be opposite to the first edge of the clock cycle of the clock signal S2.

Due to this configuration a rising edge counter and falling edge counter may be realized, which may result in a faster conversion.

The Gray ripple counter 132 may be connected to a first portion of the storage cells 122 of each of the storage circuits 120. The further Gray ripple counter 134 may be connected to a second portion of the storage cells 122 of each of the storage circuits 120. This configuration is shown in FIGS. 2A and 2B.

According to embodiment, the storage cells 122 may be static random-access memory (SRAM) cells.

Moreover, as described above, the pixel group may correspond to a column of the pixel array.

The ADC 100 may then be configured as a column-parallel ADC.

Furthermore, as explained in relation to FIGS. 1A and 1B, the image sensor 1 may comprise the ADC 100 as described above.

Although embodiments have been explained with reference to an architecture comprising a rising edge counter and a falling edge counter, it is clearly to be understood that the concept may be applied to any architecture of an ADC comprising a shared counter circuit.

While embodiments of the invention have been described above, it is obvious that further embodiments may be implemented. For example, further embodiments may comprise any subcombination of features recited in the claims or any subcombination of elements described in the examples given above. Accordingly, this spirit and scope of the appended claims should not be limited to the description of the embodiments contained herein.

### LIST OF REFERENCES

10 pixel array
20<0>, . . . , 110<i-1>, . . . , 110<i>, . . . 11<2i-1> pixel groups/columns
30 pixel
40 row selection circuit
60 ramp voltage generator
50<0>, . . . , 110<i-1>, . . . , 110<i>, . . . 11<2i-1> bus lines
80 comparator circuit
100 analog-to-digital converter (ADC)
110<0>, . . . , 110<i-1>, . . . , 110<i>, . . . 11<2i-1> ADC circuit
120<0>, . . . , 110<i-1>, . . . , 110<i>, . . . 11<2i-1> storage circuit
122 storage cells
124 storage cells
130 shared counter circuit
CO_130R<0>, . . . , CO_130R<N> counter output connections
CO_130F<0>, . . . , CO_130F<N> counter output connections
132 Gray ripple counter
134 Gray ripple counter
C131 counter control connection
C133 counter control connection
136 flip-flops
140 delay circuit
b_D bit specific delay
CLK clock
B0, . . . , BN binary output bits
G0, . . . , GN gray output bits
CNTR<0>, . . . , CNTR<N> counter bits
CNTF<0>, . . . , CNTF<N> counter bits
S1 comparison signal
S2 clock signal
S3 input signal
S4 reference signal

1. An analog-to-digital converter (ADC), comprising:
a plurality of ADC circuits, each ADC circuit being associated to a pixel group of an pixel array and comprising a storage circuit comprising a plurality of storage cells;
a shared counter circuit having a counter control connection to apply a clock signal and a plurality of counter output connections, the shared counter circuit being configured to generate a respective counter bit in response to a counter state of the counter circuit, wherein a respective one of the storage cells is connected to a respective one of the counter output connections for storing the respective counter bit, wherein the shared counter circuit (130) comprises a Gray ripple counter; and
a delay circuit the delay circuit being arranged on at least one of the counter output connections between the counter circuit and a corresponding storage cell and being configured to add to at least one counter bit a bit-specific delay to account for a ripple delay introduced by the Gray ripple counter.

2. An analog-to-digital converter (ADC), comprising:
a plurality of ADC circuits, each ADC circuit being associated to a pixel group of an pixel array and comprising a storage circuit comprising a plurality of storage cells;
a shared counter circuit having a counter control connection to apply a clock signal and a plurality of counter output connections, the shared counter circuit being configured to generate a respective counter bit in response to a counter state of the counter circuit, wherein a respective one of the storage cells is connected to a respective one of the counter output connections for storing the respective counter bit, wherein the shared counter circuit comprises a Gray ripple counter; and
a delay circuit connected to one or more storage cells of the plurality of storage cells and configured to delay a write control signal for storing a counter bit into a storage cell of the one or more storage cells, wherein the delay for the write control signal increases from lower counter bits to higher counter bits to account for a ripple delay introduced by the Gray ripple counter.

3. The ADC according to claim 2, wherein the Gray ripple counter comprises a binary ripple counter that is configured to generate binary output bits and an additional set of flip-flops, wherein the binary output bits are used as input into the set of flip-flops to generate the counter bits, wherein the counter bits are Gray counter bits.

4. The ADC according to claim 3, wherein the bit-specific delay matches a delay of a previous counter bit, MSB, generated by the binary ripple counter.

5. The ADC according to claim 2, wherein a number of delay units of the delay circuit increases from the storage cells assigned to lower counter bits to the storage cells assigned to higher counter bits.

6. The ADC according to claim 2, wherein the ADC further comprises a comparator circuit configured to generate a comparison signal in response to a comparison of an input signal and a reference signal, wherein the comparison signal is input into each one of the ADC circuits, and wherein the control write signal is based on the comparison signal.

7. The ADC according to claim 2, wherein the shared counter circuit comprises a further Gray ripple counter.

8. The ADC according to claim 7, wherein
the Gray ripple counter is configured to change its counter state, when a first edge of a clock cycle of the clock signal is applied to the Gray ripple counter,
the further Gray ripple counter is configured to change its counter state, when a second edge of the clock cycle of the clock signal being opposite to the first edge of the clock cycle of the clock signal is applied to the further Gray ripple counter.

9. The ADC according to claim 7, wherein
the output connections are connected to a first portion of the storage cells of each of the storage circuits, and
the output connections of the further Gray ripple counter are connected to a second portion of the storage cells of each of the storage circuits.

10. The ADC according to claim 2, wherein the storage cells are static random-access memory (SRAM) cells.

11. The ADC according to claim 2, wherein the pixel group corresponds to a column of the pixel array.

12. The ADC according to claim 2, wherein the ADC is configured as a column-parallel ADC.

13. An image sensor, comprising:
a pixel array including at least two pixel groups, each pixel group comprising a plurality of pixels connected to a respectively associated group bus of that pixel group; and
an analog-to-digital converter (ADC), the ADC comprising:
a plurality of ADC circuits, each ADC circuit being associated to a pixel group of a pixel array and comprising a storage circuit comprising a plurality of storage cells;
a shared counter circuit having a counter control connection to apply a clock signal and a plurality of counter output connections, the shared counter circuit being configured to generate a respective counter bit in response to a counter state of the counter circuit, wherein a respective one of the storage cells is connected to a respective one of the counter output connections for storing the respective counter bit, wherein the shared counter circuit comprises a Gray ripple counter; and
a delay circuit connected to one or more storage cells of the plurality of storage cells and configured to delay a write control signal for storing a counter bit into a storage cell of the one or more storage cells, wherein the delay for the write control signal increases from lower counter bits to higher counter bits to account for a ripple delay introduced by the Gray ripple counter.

14. The ADC according to claim 1, wherein the Gray ripple counter comprises a binary ripple counter that is con-figured to generate binary output bits and an additional set of flip-flops, wherein the binary output bits are used as input into the set of flip-flops to generate the counter bits, wherein the counter bits are Gray counter bits.

15. The ADC according to claim 14, wherein the bit-specific delay matches a delay of a previous counter bit, MSB, generated by the binary ripple counter.

16. The ADC according to claim 1, wherein a number of delay units of the delay circuit increases from the storage cells assigned to lower counter bits to the storage cells assigned to higher counter bits.

17. The ADC according to claim 1, wherein the ADC further comprises a comparator circuit configured to generate a comparison signal in response to a comparison of an input signal and a reference signal, wherein the comparison signal is input into each one of the ADC circuits, and wherein the control write signal is based on the comparison signal.
